(19) United States
(12) Patent Application Publication
(10) Pub. No.: US 2014/0183158 A1
(43) Pub. Date: Jul. 3, 2014

(54) METHOD FOR IMPROVING ANISOTROPY OF CARBON NANOTUBE FILM AND METHOD FOR MAKING TOUCH PANEL

(71) Applicant: Tianjin Funayuanchuang Technology Co., Ltd., Tianjin (CN)

(72) Inventors: CHIH-HAN CHAO, New Taipei (TW); CHIH-CHIEH CHANG, New Taipei (TW); PO-SHENG SHIH, New Taipei (TW)

(73) Assignee: Tianjin Funayuanchuang Technology Co., Ltd., Tianjin (CN)

(21) Appl. No.: 13/958,281

(22) Filed: Aug. 2, 2013

(30) Foreign Application Priority Data
Dec. 28, 2012 (CN) 201210582279X

(51) Int. Cl. H05K 3/22

(52) U.S. Cl. CPC H05K 3/22
USPC 216/13

(57) ABSTRACT

A method for improving anisotropy of a carbon nanotube film is provided. The carbon nanotube film is drawn from a carbon nanotube array. The surface of the carbon nanotube film is treated by plasma. A majority of carbon nanotubes of the carbon nanotube film are arranged to substantially extend along the same direction to form a plurality of carbon nanotube wires in parallel with each other. A minority of the carbon nanotubes of the carbon nanotube film are dispersed on a surface of the carbon nanotube film and in contact with the plurality of carbon nanotube wires.

### BACKGROUND

1. Technical Field

The present disclosure relates a method for improving anisotropy of a carbon nanotube film and a method for making a carbon nanotube based touch panel.

2. Description of Related Art

Carbon nanotube (CNT) is a new material and prepared by Japanese researcher Iijima (Helical Microtubules of Graphitic Carbon, Nature, V354, P56˜58 (1991)). Carbon nanotube film attracts more attention because of excellent electric conductivity and light transmittance.

A method for making a carbon nanotube film is disclosed by Baughman in a paper (“Strong, Transparent, Multifunctional, Carbon Nanotube Sheets” Mei Zhang, Shaoli Fang, Anvar A. Zakhidov, Ray H. Baughman, etc. Science, Vol. 309, P1215-1219 (2005)). The carbon nanotube film is pulled out from a carbon nanotube array grown on a substrate. Because the electric conductivity of the carbon nanotubes along the axial direction is much better than the electric conductivity along the radial direction, and most of the carbon nanotubes of the carbon nanotube film are substantially arranged to extend along the pulling direction, the carbon nanotube film is conductivity anisotropy. The conductivity anisotropy means that the ratio between the resistance of the carbon nanotube film not along the extending direction of the carbon nanotubes and the resistance of the carbon nanotube film along the extending direction of the carbon nanotubes. The carbon nanotube film with conductivity anisotropy can be used in electric device such as touch panel. However, the conductivity anisotropy of the carbon nanotube film cannot meet the requirement of the electric device.

What is needed, therefore, is to provide a method for improving conductivity anisotropy of the carbon nanotube film.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a scanning electron microscope (SEM) image of a first embodiment of a carbon nanotube film.

FIG. 2 is a schematic view of a carbon nanotube segment of the carbon nanotube film of FIG. 1.

FIG. 3 is a schematic view of the first embodiment of the carbon nanotube film before plasma treating.

FIG. 4 is an enlarged schematic view of part IV of the carbon nanotube film of FIG. 3.

FIG. 5 is a schematic view of the first embodiment of the carbon nanotube film after plasma treating.

FIG. 6 is a flow chart of a second embodiment of a method for improving conductivity anisotropy of the carbon nanotube film.

FIG. 7 is a flow chart of one embodiment of a method for making a touch panel.

FIG. 8 is a flow chart of another embodiment of a method for making a touch panel.

FIG. 9 is a schematic view of the touch panel made by the methods of FIG. 7 and FIG. 8.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

References will now be made to the drawings to describe, in detail, various embodiments of the present methods for improving anisotropy of the carbon nanotube films and the methods for making touch panels.

A method of a first embodiment for improving anisotropy of the carbon nanotube film, comprises following steps:

step (S1), providing a carbon nanotube film, wherein a majority of carbon nanotubes of the carbon nanotube film are arranged to substantially extend along the same direction; and

step (S2), treating the surface of the carbon nanotube film by plasma.

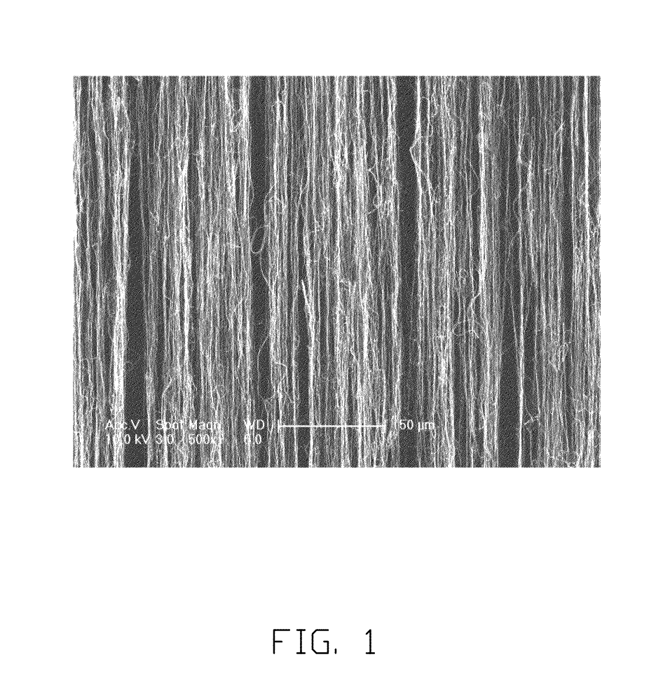

In step (S1), the carbon nanotube film is a substantially pure structure consisting of a plurality of carbon nanotubes, with few impurities and chemical functional groups as shown in FIG. 1. The carbon nanotube film is a free-standing structure. The term “free-standing structure” means that the carbon nanotube film can sustain the weight of itself when it is hoisted by a portion thereof without any significant damage to its structural integrity. Thus, the carbon nanotube film can be suspended by two spaced supports. The majority of carbon nanotubes of the carbon nanotube film are joined end-to-end by van der Waals force therebetween so that the carbon nanotube film is a free-standing structure. The carbon nanotubes of the carbon nanotube film can be single-walled, double-walled, or multi-walled carbon nanotubes. The diameter of the single-walled carbon nanotubes can be in about 0.5 nm to about 50 nm. The diameter of the double-walled carbon nanotubes can be in about 1.0 nm to about 50 nm. The diameter of the multi-walled carbon nanotubes can be in about 1.5 nm to about 50 nm.

The carbon nanotubes of the carbon nanotube film are oriented along a preferred orientation. That is, the majority of carbon nanotubes of the carbon nanotube film are arranged to substantially extend along the same direction and in parallel with the surface of the carbon nanotube film. Each adjacent two of the majority of carbon nanotubes of the carbon nanotube film are joined end-to-end by van der Waals force therebetween along the extending direction. A minority of dispersed carbon nanotubes of the carbon nanotube film may be located and arranged randomly. However, the minority of dispersed carbon nanotubes have little effect on the properties of the carbon nanotube film and the arrangement of the majority of carbon nanotubes of the carbon nanotube film. The majority of carbon nanotubes of the carbon nanotube film are not absolutely form a direct line and extend along the axial direction, some of them may be curved and in contact with each other in microcosm. Some variations can occur in the carbon nanotube film. Because the electric conductivity of the carbon nanotubes along the axial direction is much better than the electric conductivity along the radial direction, and the majority of the carbon nanotubes of the carbon nanotube film are substantially arranged to extend along the same direction, the carbon nanotube film is conductivity anisotropy.

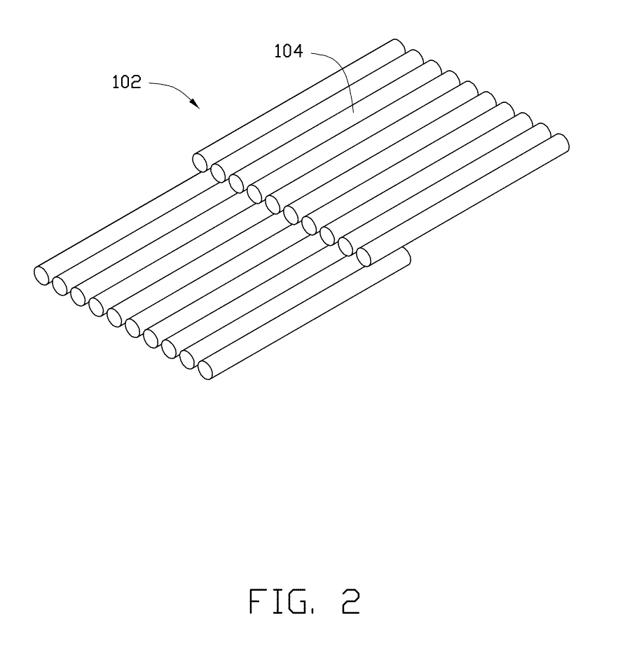

FIG. 2 shows that the carbon nanotube film includes a plurality of successively oriented carbon nanotube segments 102, joined end-to-end by van der Waals force therebetween. Each carbon nanotube segment 102 includes a plurality of carbon nanotubes 104 parallel to each other, and combined by van der Waals force therebetween. A thickness of the carbon nanotube film can range from about 0.5 nanometers to about 100 micrometers, such as 10 nanometers, 50 nanometers, 200 nanometers, 500 nanometers, 1 micrometer, 10 micrometers, or 50 micrometers. The light transmittance of the carbon nanotube film is greater than 90%. The carbon nanotube film is drawn from a carbon nanotube array. The width of the carbon nanotube film is related to the width of the carbon nanotube array. The length of the carbon nanotube film is unlimited. Examples of the carbon nanotube film are taught by U.S. Pat. No. 7,045,108 to Jiang et al., and WO 2007015710 to Zhang et al.

In one embodiment, at least two carbon nanotube films can be stacked with each other or two or more carbon nanotube films can be located coplanarly and combined by only the van der Waals force therebetween. Additionally, the orientations of carbon nanotubes in adjacent carbon nanotube films, whether stacked or adjacent, are the same. Stacking the carbon nanotube films will also add to the structural integrity of the carbon nanotube film.

The carbon nanotube film can be made by following substeps:

step (S10), providing a carbon nanotube array on a substrate; and

step (S12), drawing out the carbon nanotube film from the carbon nanotube array by using a tool. In step (S10), the carbon nanotube array includes a plurality of carbon nanotubes that are parallel to each other and substantially perpendicular to the substrate. The height of the plurality of carbon nanotubes can be in a range from about 50 micrometers to 900 micrometers. The carbon nanotube array can be formed by the substeps of: step (S101) providing a substantially flat and smooth substrate; step (S102) forming a catalyst layer on the substrate; step (S103) annealing the substrate with the catalyst layer in air at a temperature approximately ranging from 700° C. to 900° C. for about 30 minutes to 90 minutes; step (S104) heating the substrate with the catalyst layer to a temperature approximately ranging from 500° C. to 740° C. in a furnace with a protective gas therein; and step (S105) supplying a carbon source gas to the furnace for about 5 minutes to 30 minutes and growing the carbon nanotube array on the substrate.

In step (S101), the substrate can be a P-type silicon wafer, an N-type silicon wafer, or a silicon wafer with a film of silicon dioxide thereon. A 4-inch P-type silicon wafer is used as the substrate. In step (S102), the catalyst can be made of iron (Fe), cobalt (Co), nickel (Ni), or any alloy thereof. In step (S103), the protective gas can be made up of at least one of nitrogen (N₂), ammonia (NH₃), and a noble gas. In step (S105), the carbon source gas can be a hydrocarbon gas, such as ethylene (C₂H₄), methane (CH₄), acetylene (C₂H₂), ethane (C₂H₆), or any combination thereof. The carbon nanotube array formed under the above conditions is essentially free of impurities, such as carbonaceous or residual catalyst particles.

In step (S12), the drawing out the carbon nanotube film includes the substeps of: step (S121) selecting one or more of carbon nanotubes in a predetermined width from the carbon nanotube array; and step (S122) drawing the selected carbon nanotubes to form nanotube segments at an even and uniform speed to achieve the carbon nanotube film. The carbon nanotube film has the smallest resistance along the drawing direction and the greatest resistance along a direction perpendicular to the drawing direction. Thus, the carbon nanotube film is resistance anisotropy.

In step (S121), the carbon nanotubes having a predetermined width can be selected by using an adhesive tape, such as the tool, to contact the super-aligned array. In step (S122), the drawing direction is substantially perpendicular to the growing direction of the carbon nanotube array. Each carbon nanotube segment includes a plurality of carbon nanotubes parallel to each other.

In one embodiment, during the drawing process, as the initial carbon nanotube segments are drawn out, other carbon nanotube segments are also drawn out end-to-end due to van der Waals force between ends of adjacent segments. This process of drawing helps provide a continuous and uniform carbon nanotube film having a predetermined width can be formed.

The width of the carbon nanotube film depends on a size of the carbon nanotube array. The length of the carbon nanotube film can be arbitrarily set as desired. In one useful embodiment, when the substrate is a 4-inch P-type silicon wafer, the width of the carbon nanotube film can be in a range from about 0.01 centimeters to about 10 centimeters. The thickness of the carbon nanotube film can be in a range from about 0.5 nanometers to about 10 micrometers.

In step (S2), the plasma is usually a gas group with high energy. The plasma is one of the four fundamental states of matter (the others being solid, liquid, and gas). Heating a gas may ionize its molecules or atoms (reducing or increasing the number of electrons in them), thus turning it into a plasma, which contains charged particles such as, positive ions, free electrons, or negative ions, and non-charged particles such as atom and molecule. However, total charge of the plasma is neutral. Ionization can be induced by other means, such as strong electromagnetic field applied with a laser or microwave generator, and is accompanied by the dissociation of molecular bonds, if present. The strong electromagnetic field would make the outer electrons no longer to be bound to the nucleus and become a free electron with high energy. The plasma is highly excited and unstable state.

The principle of improving conductivity anisotropy of the carbon nanotube film by treating the surface of the carbon nanotube film with plasma is provided below.

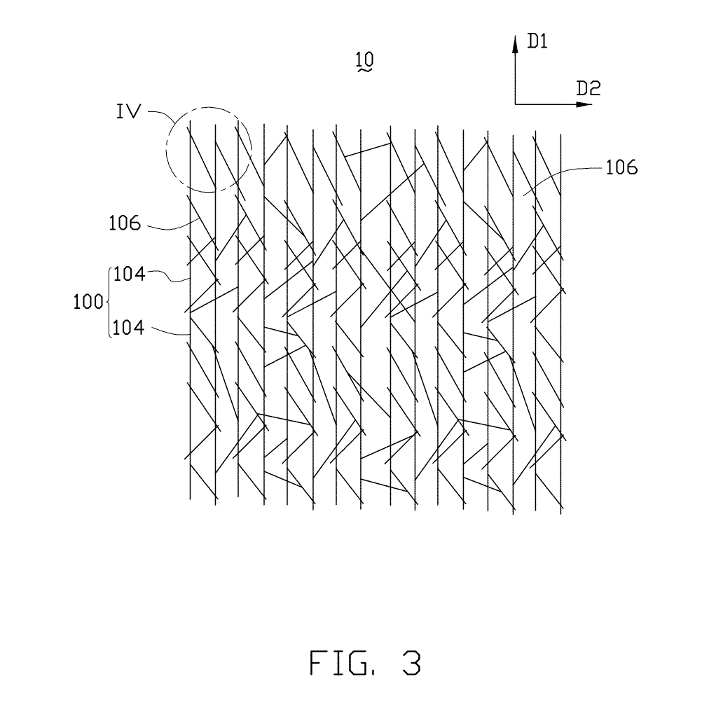

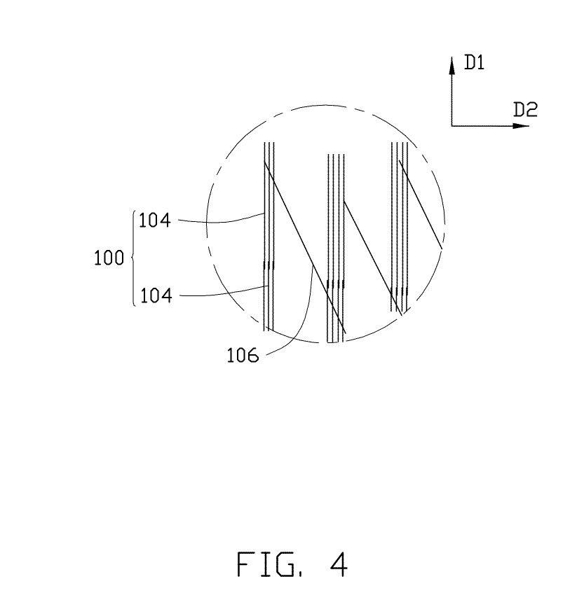

FIGS. 3-4 show that in the carbon nanotube film 10, the majority of the carbon nanotubes 104 are arranged to extend along the same direction to form a plurality of carbon nanotube wires 100 in parallel with each other. The minority of the carbon nanotubes 106 are dispersed on the surface of the carbon nanotube film 10 and in contact with the plurality of carbon nanotube wires 100. The carbon nanotubes 104 of each of the plurality of carbon nanotube wires 100 that is along the length are joined end to end. The carbon nanotubes 104 of each of the plurality of carbon nanotube wires 100 that is perpendicular with the length are parallel with each other to form the carbon nanotubes segments 102 as shown in FIG. 2. Thus, the plurality of carbon nanotube wires 100 form a plurality of conductive paths of the carbon nanotube film 10 along the extending direction of the carbon nanotubes 104. The conductivity of the carbon nanotube film 10 not along the extending direction of the carbon nanotubes 104 mainly depend on the minority of the carbon nanotubes 106.

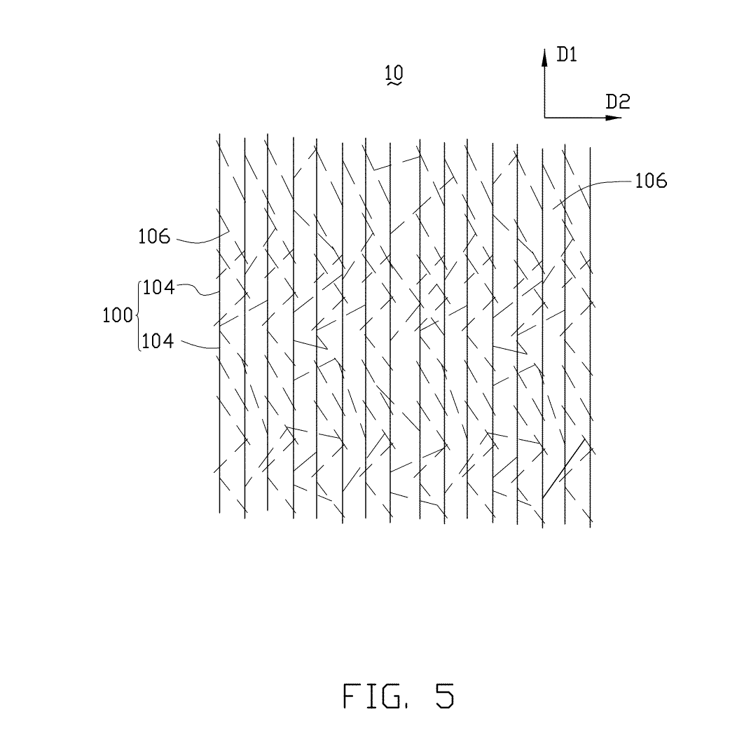

FIG. 5 shows that the carbon nanotubes 104 and carbon nanotubes 106 will be damaged to form defects or broken after plasma treating because the plasma etches the surface of the carbon nanotube film 10 during plasma treating. Thus, the resistance of the carbon nanotube film 10 along each direction will be increased. However, the break and defects of a few of the carbon nanotubes 104 will not cause the carbon nanotube wires 100 to be broken, thus, the resistance increase of the carbon nanotube film 10 along the extending direction of the carbon nanotubes 104 is relatively small. The break and defects of a few of the carbon nanotubes 106 will cause the resistance of the carbon nanotube film 10 not along the extending direction of the carbon nanotubes 104 to be increased significantly. Especially, along the direction perpendicular to the extending direction of the carbon nanotubes 104, the resistance increase of the carbon nanotube film 10 is greatest. Therefore, the resistance increase of the carbon nanotube film 10 not along the extending direction of the carbon nanotubes 104 is much greater that the resistance increase of the carbon nanotube film 10 along the extending direction of the carbon nanotubes 104. That is, the conductivity anisotropy of the carbon nanotube film 10 is improved after plasma treating.

In one embodiment, the length of the carbon nanotube wires 100 is defined as a direction D1, and the direction that is perpendicular with the length of the carbon nanotube wires 100 is defined as a direction D2. The conductivity of the carbon nanotube film 10 is tested before and after plasma treating. It is found that the resistance of the carbon nanotube film 10 along the direction D1 is substantially unchanged before and after plasma treating, but the resistance of the carbon nanotube film 10 along the direction D2 after plasma treating is about at least 5 times as the resistance of the carbon nanotube film 10 along the direction D2 before plasma treating. That is, the conductivity anisotropy of the carbon nanotube film 10 after plasma treating is up to at least 5 times as the conductivity anisotropy of the carbon nanotube film 10 before plasma treating. In one embodiment, the conductivity anisotropy of the carbon nanotube film 10 after plasma treating is up to 10 times to 20 times as the conductivity anisotropy of the carbon nanotube film 10 before plasma treating.

According to the formula W=I²R, where the resistance R is greater, the power of the plasma treating W is greater. Because the good conductivity anisotropy of the carbon nanotube film 10, the resistance of the carbon nanotube film 10 not along the direction D1 is much greater than the resistance of the carbon nanotube film 10 along the direction D1. Thus, the power of the plasma treating W not along the direction D1 is much greater than the power of the plasma treating W along the direction D1. Thus, the minority of dispersed carbon nanotubes 106 are easy to be damaged to form defects or broken after plasma treating. The conductivity anisotropy of the carbon nanotube film 10 is improved significantly after plasma treating.

The plasma treating the carbon nanotube film 10 is performed by applying plasma energy on the entire or part surface of the carbon nanotube film 10 via a plasma treating device. The plasma gas can be an inert gas and/or etching gases, such as argon (Ar), helium (He), hydrogen (H₂), oxygen (O₂), fluorocarbon (CF₄), ammonia (NH₃), or air. The power of the plasma treating device can be in a range from about 50 watts to about 1000 watts, such as 100 watts, 200 watts, 500 watts, 700 watts, or 800 watts. The plasma flow can be in a range from about 5 sccm to about 100 sccm, such as 10 sccm, 20 sccm, 50 sccm, 70 sccm, or 80 sccm. When the plasma is produced in vacuum, the work pressure of the plasma can be in a range from about 40 mTorr to about 150 mTorr, such as 50 mTorr, 60 mTorr, 70 mTorr, 80 mTorr, 100 mTorr, 120 mTorr, or 130 mTorr. When the plasma is produced under a standard atmospheric pressure, the work pressure of the plasma can be about 760 Torr. The time for plasma treating can be in a range from about 0.1 seconds to about 50 seconds, such as 0.5 seconds, 1 seconds, 5 seconds, 10 seconds, or 30 seconds. The time for plasma treating must be short in order to prevent many carbon nanotubes of the carbon nanotube wires 100 from breaking causing poor conductivity of the carbon nanotube film 10 along the direction D1 after plasma treating. In one embodiment, it is prefered to control the time for plasma treating as long as is needed to just substantially break all the minority of dispersed carbon nanotubes 106.

Furthermore, a step of placing the carbon nanotube film 10 on a surface of a substrate (not shown) can be performed during the plasma treating. The size and shape of the substrate can be selected according to need. The substrate may be material such as glass, ceramic, quartz, diamond, polymers, semiconductors, silicon oxide, metal oxide, or wood. The substrate is used to protect the carbon nanotube film 10 and prevent the carbon nanotube film 10 from being broken. After plasma treating, the macrostructure of the carbon nanotube film 10 are substantially unchanged. The carbon nanotubes of the carbon nanotube film 10 still form an integral film structure with improved conductivity anisotropy and uniform light transparency. That is, the carbon nanotubes of the carbon nanotube film 10 are only damaged to form defects/cracks or broken by during the plasma treating in microcosm.

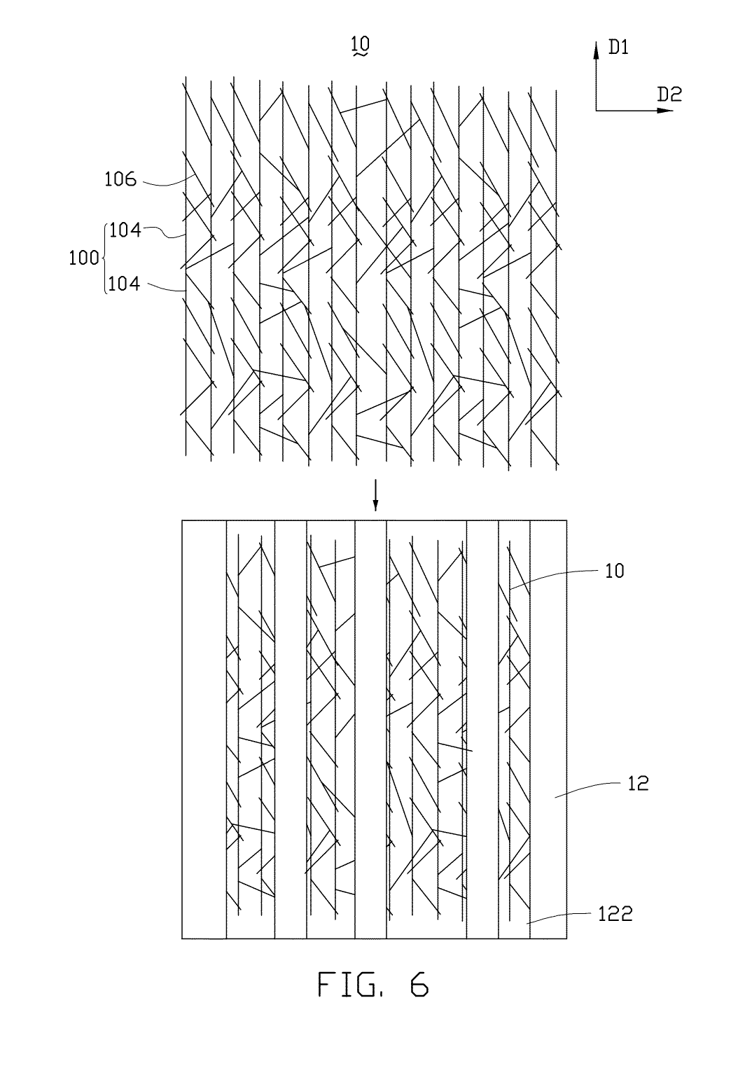

FIG. 6 shows that a method of a second embodiment for improving anisotropy of the carbon nanotube film comprises following steps:

step (S1A), providing a carbon nanotube film 10, wherein a majority of carbon nanotubes 104 of the carbon nanotube film 10 are arranged to substantially extend along the same direction to form a plurality of carbon nanotube wires 100 in parallel with each other, and a minority of the carbon nanotubes 106 are dispersed on the surface of the carbon nanotube film 10 and in contact with the plurality of carbon nanotube wires 100;

step (S2A), applying a mask 12 on the carbon nanotube film 10 so that part of the carbon nanotube film 10 is exposed through the mask 12 to form an exposed area; and

step (S3A), treating the exposed area of the carbon nanotube film 10 by plasma.

The method of the second embodiment is similar to the method of the first embodiment except that the mask 12 is used to shield part of the carbon nanotube film 10 so that the plasma treats only the exposed area of the carbon nanotube film 10.

In step (S2A), the mask 12 can be in contact with the carbon nanotube film 10 or spaced from the carbon nanotube film 10. The mask 12 can be made of material such as glass, ceramic, quartz, diamond, polymers, semiconductors, silicon oxide, or metal oxide. The size and shape of the mask 12 can be selected according to need. The mask 12 defines a plurality of openings 122 so the part of the carbon nanotube film 10 is exposed to form the exposed area. The size and shape of each of the plurality of openings 122 can be selected according to need. In one embodiment, the mask 12 includes a composite of a polyethylene terephthalate (PET) sheet and a carbon nanotube film on the PET sheet. The mask 12 defines a plurality of rectangular openings 122 in parallel with each other. The extending direction of each rectangular opening 122 is along the direction D1. The conductivity anisotropy of the exposed area of the carbon nanotube film 10 is improved after plasma treating.

A method of a third embodiment for improving anisotropy of the carbon nanotube film comprises following steps:

step (S1B), providing a carbon nanotube film, wherein a majority of carbon nanotubes of the carbon nanotube film are arranged to substantially extend along the same direction; and

step (S2B), treating the surface of the carbon nanotube film by corona.

The method of the third embodiment is similar to the method of the first embodiment except that the surface of the carbon nanotube film is treated by corona in step (S2B).

In step (S2B), the treating the surface of the carbon nanotube film by corona includes corona discharging on the surface of the carbon nanotube film under a high frequency alternating voltage to produce low temperature plasma to etch the carbon nanotube film. The alternating voltage can be in a range from about 5000 V/m² to about 15000V/m². In one embodiment, the treating the surface of the carbon nanotube film by corona is similar to the treating the surface of the carbon nanotube film by plasma except that the carbon nanotube film is used as an electrode for corona discharging during corona treating. Because the carbon nanotubes of the carbon nanotube film have a plurality of sharp ends with diameter in nanometer scale, more plasma can be produced by corona discharging during corona treating.

A method of a fourth embodiment for improving anisotropy of the carbon nanotube film comprises following steps:

step (S1C), providing a carbon nanotube film, wherein a majority of carbon nanotubes of the carbon nanotube film are arranged to substantially extend along the same direction;

step (S2C), applying a mask on the carbon nanotube film so that part of the carbon nanotube film is exposed through the mask to form an exposed area; and

step (S3C), treating the surface of the carbon nanotube film by corona.

The method of the fourth embodiment is similar to the method of the third embodiment except that the mask is used to shield part of the carbon nanotube film so that only the exposed area of the carbon nanotube film is treated by the corona.

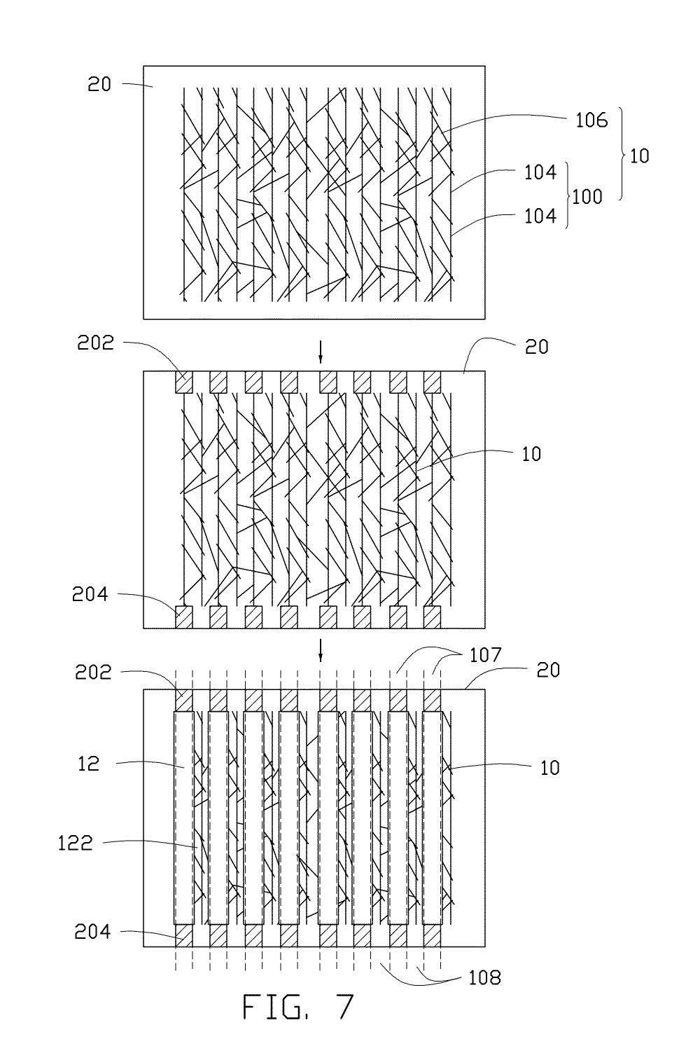

FIG. 7 shows that a method of a fifth embodiment for making a touch panel comprises following steps:

step (S1D), placing the carbon nanotube film 10 on a surface of a substrate 20, wherein a majority of carbon nanotubes 104 of the carbon nanotube film 10 are arranged to substantially extend along the same direction to form a plurality of carbon nanotube wires 100 in parallel with each other, and a minority of the carbon nanotubes 106 are dispersed on the surface of the carbon nanotube film 10 and in contact with the plurality of carbon nanotube wires 100;

step (S2D), forming a plurality of first electrodes 202 and a plurality of second electrodes 204 so that the plurality of carbon nanotube wires 100 extending from the plurality of first electrodes 202 to the plurality of second electrodes 204;

step (S3D), applying a mask 12 on the carbon nanotube film 10 so that part of the carbon nanotube film 10 is exposed through the mask 12 to form an exposed area; and

step (S4D), treating the exposed area of the carbon nanotube film 10 by plasma.

In step (S1D), the substrate 20 is configured to support the carbon nanotube film 10, the plurality of first electrodes 202, and the plurality of second electrodes 204. The substrate 20 can be a film or a sheet. The substrate 20 can be flat or curved. The substrate 20 can be opaque or transparent. The substrate 20 can be made of rigid materials such as glass, quartz, diamond, plastic or any other suitable material. The substrate 20 can also be made of flexible materials such as polycarbonate (PC), polymethyl methacrylate acrylic (PMMA), polyimide (PI), PET, polyethylene (PE), polyether polysulfones (PES), polyvinyl polychloride (PVC), benzocyclobutenes (BCB), acrylonitrile-butadiene-styrene copolymer (ABS), polyamide (PA), polyesters, or acrylic resin. The thickness of the substrate 20 can be in a range from about 100 micrometers to about 1000 micrometers. In one embodiment, the substrate 20 is a flat PET sheet with a thickness of about 200 micrometers. The substrate 20 is transparent with a light transmittance greater than 75%, especially greater than 90%.

Furthermore, a step of forming an adhesive layer (not shown) on the substrate 20 can be performed before placing the carbon nanotube film 10. The adhesive layer is configured to fix the carbon nanotube film 10 on the substrate 20. The adhesive layer can be transparent, opaque, or translucent. The adhesive layer can be a UV glue layer or optically clear adhesive (OCA) layer. The OCA layer is a clear and transparent double-sided adhesive tape with a light transmittance greater than 99%. Material of the OCA layer is polymethyl methacrylate (PMMA), which also named as Plexiglas or acrylic. The thickness of the adhesive layer can be in a range from about 1 nanometer to about 500 micrometers, for example, the thickness is in a range from about 1 micrometer to about 2 micrometers. In one embodiment, the adhesive layer is a UV glue layer with a thickness of about 1.5 micrometers.

In step (S2D), the plurality of first electrodes 202 and the plurality of second electrodes 204 can be located on the substrate 20 and electrically connected with the carbon nanotube film 10. In one embodiment, the plurality of first electrodes 202 and the plurality of second electrodes 204 are located on a surface of the carbon nanotube film 10. The location of the first electrodes 202 and the second electrodes 204 depends on the work principle and detecting process of the touch screen using the touch panel. The number of the first electrodes 202 and the second electrodes 204 depends on the resolution ratio and area of the touch screen using the touch panel. In one embodiment, eight first electrodes 202 and eight second electrodes 204 are located on two opposite sides of the carbon nanotube film 10 one by one. Each corresponding pair of the first electrodes 202 and the second electrodes 204 are electrically connected by at least one carbon nanotube wire 100. The plurality of second electrodes 204 can be omitted.

The first electrodes 202 and the second electrodes 204 can be made of material such as metal, carbon nanotube, conductive polymer, conductive silver paste, or ITO. The first electrodes 202 and the second electrodes 204 can be made by etching a metal film, etching an ITO film, or printing a conductive silver paste. The shape of the first electrodes 202 and the second electrodes 204 can be selected according to need, such as elliptical, rectangular, square, triangular or round. In one embodiment, the first electrodes 202 and the second electrodes 204 are made by printing conductive silver paste concurrently.

The carbon nanotube film 10 defines a plurality of first rectangular areas 107 and a plurality of second rectangular areas 108 alternately located on the substrate 20. Each of the plurality of first rectangular areas 107 is located between and electrically connected with each corresponding pair of the first electrodes 202 and the second electrodes 204. The plurality of second rectangular areas 108 are not electrically connected with the first electrodes 202 and the second electrodes 204.

In step (S3D), the mask 12 defines a plurality of rectangular openings 122 in parallel with each other. The extending direction of each rectangular opening 122 is along the length of the carbon nanotube wires 100. The mask 12 only shields the part of the carbon nanotube film 10 that on the plurality of first rectangular areas 107 so that the part of the carbon nanotube film 10 that on the plurality of second rectangular areas 108 is exposed to form the exposed area.

In step (S4D), the exposed area of the carbon nanotube film 10 can be treated directly by plasma or by corona. Because the part of the carbon nanotube film 10 that on the plurality of first rectangular areas 107 is shielded by the mask 12 and cannot be etched by the plasma, the resistance of the part of the carbon nanotube film 10 that on the plurality of first rectangular areas 107 will not change substantially. However, the resistance of the part of the carbon nanotube film 10 that on the plurality of second rectangular areas 108 will be increased along or not along the length of the carbon nanotube wires 100. Thus, the conductivity anisotropy of the carbon nanotube film 10 is improved significantly after plasma treating.

The greater the resistance of the part of the carbon nanotube film 10 that on the plurality of second rectangular areas 108, the greater the conductivity anisotropy of the carbon nanotube film 10. That is, in step (S4D), the time for plasma treating can be more than 150 seconds. Namely, the plasma treating not only can break the dispersed carbon nanotubes 106 in the exposed area, but also can break the carbon nanotube wires 100 in the exposed area. Thus, the conductivity anisotropy of the carbon nanotube film 10 is improved much more significantly after plasma treating.

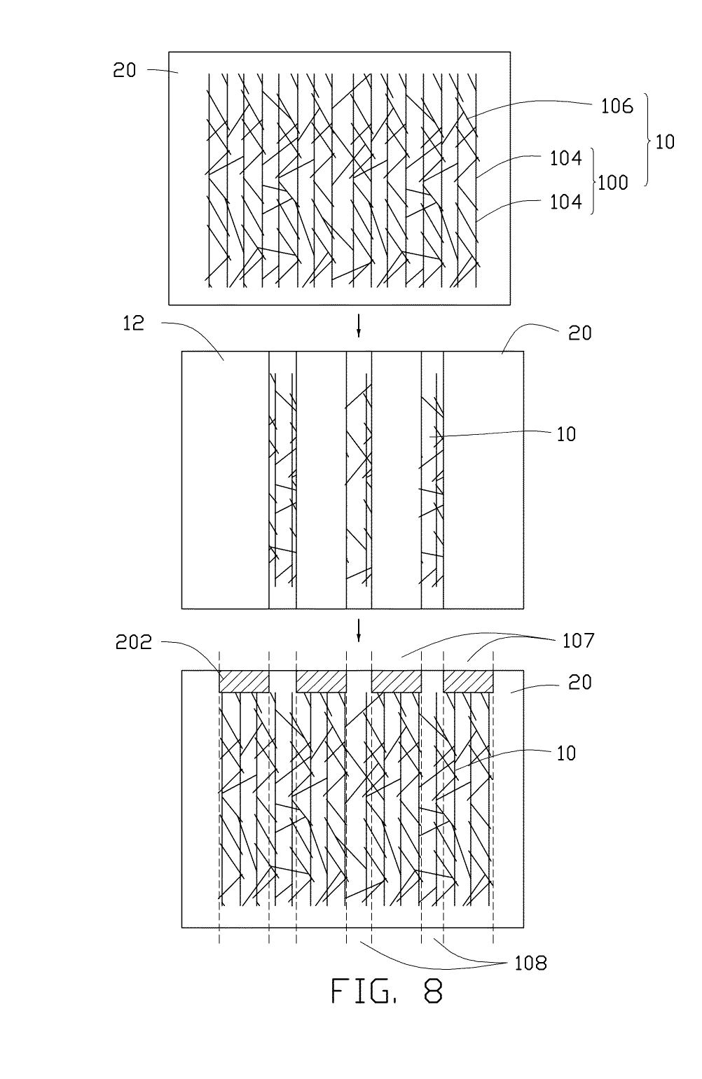

FIG. 8 shows that a method of a sixth embodiment for making a touch panel comprises following steps:

step (S1E), placing the carbon nanotube film 10 on a surface of a substrate 20, wherein a majority of carbon nanotubes 104 of the carbon nanotube film 10 are arranged to substantially extend along the same direction to form a plurality of carbon nanotube wires 100 in parallel with each other, and a minority of the carbon nanotubes 106 are dispersed on the surface of the carbon nanotube film 10 and in contact with the plurality of carbon nanotube wires 100;

step (S2E), applying a mask 12 on the carbon nanotube film 10 so that part of the carbon nanotube film 10 is exposed through the mask 12 to form an exposed area;

step (S3E), treating the exposed area of the carbon nanotube film 10 by plasma to form an untreated part; and

step (S4E), forming a plurality of first electrodes 202 to electrically connect with the carbon nanotube film 10 on the untreated area.

In step (S2E), the carbon nanotube film 10 defines a plurality of first rectangular areas 107 shielded by the mask 12 and a plurality of second rectangular areas 108 exposed through the mask 12. The plurality of first rectangular areas 107 and the plurality of second rectangular areas 108 are alternately located on the substrate 20.

In step (S4E), only the plurality of first electrodes 202 are formed on one side of the substrate 20 and electrically connect with the carbon nanotube film 10 that on the plurality of first rectangular areas 107. The plurality of first electrodes 202 can be formed before or after removing the mask 12.

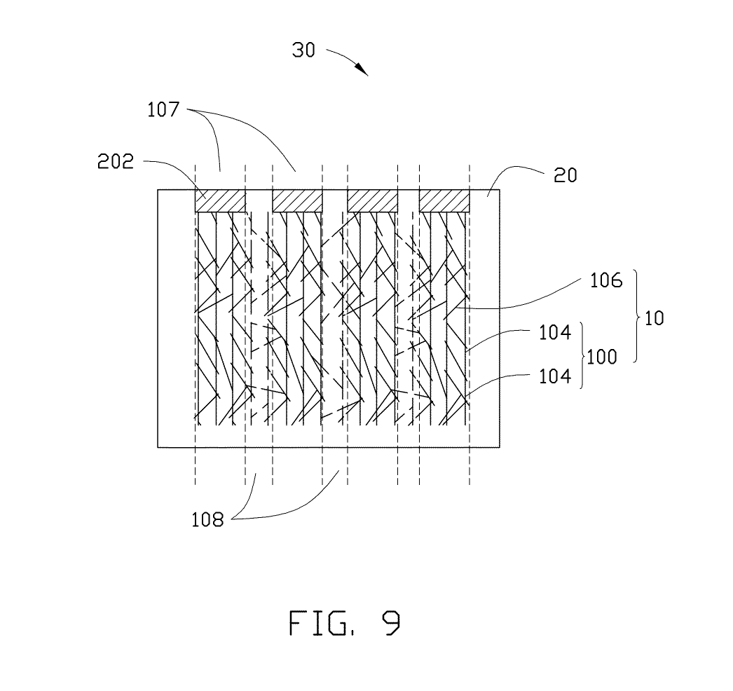

FIG. 9 shows one embodiment of the touch panel 30 provided by above embodiments comprises a substrate 20, a carbon nanotube film 10 located on a surface of the substrate 20, and a plurality of first electrodes 202 electrically connect with the carbon nanotube film 10.

The plurality of first electrodes 202 can be located on a surface of the substrate 20 or on a surface of the carbon nanotube film 10. The plurality of first electrodes 202 are located along the same side of the carbon nanotube film 10 and spaced from each other.

A majority of carbon nanotubes 104 of the carbon nanotube film 10 are arranged to substantially extend along the same direction to form a plurality of carbon nanotube wires 100 in parallel with each other. A minority of the carbon nanotubes 106 are dispersed on the surface of the carbon nanotube film 10 and in contact with the plurality of carbon nanotube wires 100. The carbon nanotube film 10 defines a plurality of first rectangular areas 107 and a plurality of second rectangular areas 108 alternately located on the substrate 20. The extending direction of each of the plurality of first rectangular areas 107 and the plurality of second rectangular areas 108 is along the length of the carbon nanotube wires 100. Each of the plurality of first rectangular areas 107 is electrically connect with at least one of the plurality of first electrodes 202.

The dispersed carbon nanotubes 106 in the plurality of second rectangular areas 108 are substantially broken, that is at least 60% of the dispersed carbon nanotubes 106 in the plurality of second rectangular areas 108 are broken. In one embodiment, at least 70% of the dispersed carbon nanotubes 106 in the plurality of second rectangular areas 108 are broken. In one embodiment, at least 80% of the dispersed carbon nanotubes 106 in the plurality of second rectangular areas 108 are broken. In one embodiment, at least 90% of the dispersed carbon nanotubes 106 in the plurality of second rectangular areas 108 are broken.

The carbon nanotube wires 100 in the plurality of second rectangular areas 108 are also substantially broken, that is at least 60% of the carbon nanotube wires 100 in the plurality of second rectangular areas 108 are broken. In one embodiment, at least 70% of the carbon nanotube wires 100 in the plurality of second rectangular areas 108 are broken. In one embodiment, at least 80% of the carbon nanotube wires 100 in the plurality of second rectangular areas 108 are broken. In one embodiment, at least 90% of the carbon nanotube wires 100 in the plurality of second rectangular areas 108 are broken.

Because both the dispersed carbon nanotubes 106 and the carbon nanotube wires 100 in the plurality of second rectangular areas 108 are substantially broken, the resistance of the carbon nanotube film 10 that on the plurality of second rectangular areas 108 will be much greater than the resistance of the carbon nanotube film 10 that on the plurality of first rectangular areas 107. Thus, the conductivity anisotropy of the carbon nanotube film 10 increases.

The touch panel 30 can be utilized in resistance-type touch screen and/or capacitance-type touch screen.

It is to be understood that the above-described embodiments are intended to illustrate rather than limit the disclosure. Any elements described in accordance with any embodiments is understood that they can be used in addition or substituted in other embodiments. Embodiments can also be used together. Variations may be made to the embodiments without departing from the spirit of the disclosure. The above-described embodiments illustrate the scope of the disclosure but do not restrict the scope of the disclosure.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What is claimed is:

1. A method for improving anisotropy of a carbon nanotube film, the method comprising:
making the carbon nanotube film comprising a plurality of carbon nanotubes, wherein the plurality of carbon nanotubes comprises a first set and a second set; and the first set are arranged to substantially extend along a same direction to form a plurality of carbon nanotube wires in parallel with each other, and the second set is on a surface of the carbon nanotube film and in contact with the plurality of carbon nanotube wires; and
treating the surface of the carbon nanotube film with plasma.

2. The method of claim 1, wherein the making the carbon nanotube film comprises:
making a carbon nanotube array on a substrate; and
drawing out the carbon nanotube film from the carbon nanotube array.

3. The method of claim 1, wherein the carbon nanotube film is a free-standing structure.

4. The method of claim 1, wherein the carbon nanotube film is a substantially pure structure consisting of the plurality of carbon nanotubes.

5. The method of claim 1, wherein in each of the plurality of carbon nanotube wires, the carbon nanotubes therein are joined end to end.

6. The method of claim 1, wherein the treating the surface of the carbon nanotube film with the plasma comprises applying plasma energy on the surface of the carbon nanotube film via a plasma treating device.

7. The method of claim 6, wherein plasma gas of the plasma is selected from the group consisting of argon gas, helium gas, hydrogen gas, oxygen gas, four carbon fluoride gas, ammonia gas, and air.

8. The method of claim 6, wherein a power of the plasma treating device is in a range from about 50 watts to about 1000 watts.

9. The method of claim 6, wherein a flow of the plasma is in a range from about 5 sccm to about 100 sccm.

10. The method of claim 6, wherein the plasma is produced in vacuum, and a work pressure of the plasma is in a range from about 40 mTorr to about 150 mTorr; or the plasma is produced under a standard atmospheric pressure, and the work pressure of the plasma is about 760 Torr.

11. The method of claim 6, wherein a time of the treating the surface of the carbon nanotube film by plasma is in a range from about 0.1 seconds to about 50 seconds.

12. The method of claim 1, wherein the treating the surface of the carbon nanotube film by plasma comprises corona discharging on the surface of the carbon nanotube film under a high frequency alternating voltage.

13. The method of claim 1, further comprising placing the carbon nanotube film on a surface of a substrate before the treating the surface of the carbon nanotube film by plasma.

14. The method of claim 1, further comprising applying a mask on the carbon nanotube film before the treating the surface of the carbon nanotube film by plasma.

15. A method for improving anisotropy of a carbon nanotube film, the method comprising:
drawing the carbon nanotube film from a carbon nanotube array; and
applying plasma energy on the surface of the carbon nanotube film.

16. A method for making a touch panel, the method comprising:
placing a carbon nanotube film on a surface of a substrate;
applying a mask on the carbon nanotube film so that part of the carbon nanotube film is exposed through the mask to form an exposed area; and
treating the exposed area of the carbon nanotube film with plasma.

17. The method of claim 16, wherein the carbon nanotube film comprises a plurality of carbon nanotubes, the plurality of carbon nanotubes comprises a first set and a second set; and the first set are arranged to substantially extend along a same direction to form a plurality of carbon nanotube wires in parallel with each other, and the second set is on a surface of the carbon nanotube film and in contact with the plurality of carbon nanotube wires.

18. The method of claim 16, wherein the carbon nanotube film defines a plurality of first rectangular areas shielded by the mask and a plurality of second rectangular areas exposed through the mask.

19. The method of claim 18, further forming a plurality of first electrodes that electrically connect with the plurality of first rectangular areas.

20. The method of claim 16, wherein the treating the exposed area of the carbon nanotube film with the plasma comprises corona discharging on the exposed area of the carbon nanotube film under a high frequency alternating voltage.
